(19) United States
(12) Patent Application Publication
(10) Pub. No.: US 2009/0081592 A1
(43) Pub. Date: Mar. 26, 2009

(54) FOUNTAIN SOLUTION COMPOSITION FOR LITHOGRAPHIC PRINTING AND HEAT-SET OFFSET ROTARY PRINTING PROCESS

(75) Inventors: Akimitsu HAIJIMA, Haibara-gun (JP); Hideyuki Hattori, Haibara-gun (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM CORPORATION, Tokyo (JP)

(21) Appl. No.: 12/237,702

(22) Filed: Sep. 25, 2008

(30) Foreign Application Priority Data
Sep. 26, 2007 (JP) 2007-248932
Aug. 27, 2008 (JP) 2008-218651

(51) Int. Cl. G03F 7/26; G03F 7/00

(52) U.S. Cl. 430/302; 430/331

(57) ABSTRACT

A fountain solution composition for lithographic printing characterized by comprising at least one acyclic hydrocarbon diol compound, having 6 to 8 carbon atoms in total and two —OH groups, wherein said two —OH groups bind to carbon atoms at 1- and 2-positions, respectively; said fountain solution composition can be used to improve blanket piling.

### BACKGROUND OF THE INVENTION

1. Field of the Invention

The present invention relates to fountain solution compositions for lithographic printing, more specifically to fountain solution compositions for offset printing process, which are preferably used for a rotary heat-set offset printing process.

2. Description of the Related Art

Lithographic printing is a process of printing, which advantageously utilizes the property that water and oil are essentially not miscible with each other, and consists of two areas: one receives water and repels an oil based ink, and the other receives the oil based ink and repels water. The former one is the non-image area, and the latter is the image area. Wetting the non-image area with a fountain solution enlarges the surface chemical difference between the image and non-image areas, thereby enhancing the ink repellency of the non-image area and the ink receptivity of the image area.

Lithographic printing machines typically employ offset printing methods, in which ink and fountain solution are supplied onto the plate where ink attaches to the image area and fountain solution attaches to the non-image area to create an image, which image on the plate in turn becomes transferred to the blanket and then to the paper from the blanket, thereby achieving printing. During this procedure, when continuing printing for a long period of time, there causes a problem so-called “blanket piling”, where the ink component and paper component gradually pile up on the non-image areas on the blanket. Specifically, rotary lithographic offset (rotary offset) printing is characterized by its long-term and continuous operatability and high productivity, however, had a considerable problem of causing blanket piling.

In the blanket piling phenomena, the ink on the image area tends to be extruded and deposited on especially the back side of the rotation (the gripper end side), and said deposition inhibits ink transfer from the blanket to paper resulting in insufficient attachment of ink. In order to remove the deposit, printing operation has to be stopped for cleaning the blanket, giving rise remarkably to increase in paper waste and reduction of the productivity. Therefore, an improvement has been demanded.

Some solutions for blanket piling have been proposed such as an ink composition for rotary lithographic offset printing comprising lanoline with an acid value of less than 1.0 in an amount of 1-5% by weight (see Patent Document 1), and a pigment coated paper for offset printing characterized by being coated with a coating composition wherein a ratio between a particular adhesive agent and the pigment is defined (see Patent Document 2).

However, limitation to particular inks or printing papers cannot be satisfactory under circumstances where use of wide variety of inks or papers is desired. Therefore, improvement of blanket piling still remains as an important issue.

Commonly known fountain solutions include aqueous solutions containing alkali metal salt or ammonium salt of dichromic acid, phosphorus acid or salt thereof such as ammonium phosphate, gum Arabic, colloid substances such as carboxymethyl cellulose (CMC) and the like. However, fountain solution containing only these compounds has a drawback in that it shows a difficulty in wetting the non-image area of the plate evenly and often causes undesired stains on the printed matters. Also, there has been a problem that the control of fountain solution supply requires substantial training.

In order to improve the above drawback, Dahlgren system using an aqueous solution containing 20-25% of isopropyl alcohol has been proposed. This method is advantageous in many points, including operationality and quality of the printed matters, by improving wetting of the non-image area, reducing the required amount of fountain solution, facilitating balancing of the amounts of printing ink and water to be supplied, reducing the emulsifying amount of fountain solution into the printing ink and further by improving the transfer efficiency of the printing ink to the blanket. However, as isopropyl alcohol is volatile, a special apparatus is required in order to maintain a certain level of isopropyl alcohol in fountain solution, which leads to an increase of the cost. Further, isopropyl alcohol has a peculiar unpleasant odor, and a toxicity problem, therefore not favorable for the working environment. Application of a fountain solution containing isopropyl alcohol to offset printing where a common dampening roller is used has been problematic since isopropyl alcohol evaporates on the roller and on the plate surface and fails in exerting its effect.

Fountain solutions free from isopropyl alcohol have been proposed such as a fountain solution containing particular propylene glycol compounds (see Patent Document 3), a fountain solution containing compounds with ethylenediamine to which ethylene oxide and propylene oxide are attached (see Patent Documents 4 and 5), and a fountain solution containing compounds with ethylenetriamine to which ethylene oxide and propylene oxide are attached (see Patent Document 6). However, these still tended to cause blanket piling, and an improvement thereof has been demanded.

On the other hand, a technique using a water-soluble organic polymer for improving wettability of printing cylinder has been proposed and it utilizes a fountain solution containing naturally occurring collagen/elastin, which are soluble to a weak acid aqueous medium (see Patent Document 7). It is also disclosed therein that the wettability becomes further improved by inclusion of a long chain (n≧6) non-polymeric alcohol and/or alkane diol having a hydroxyl group at (1,2)- or (1,3)-position.

Some examples of using diol compounds in fountain solution compositions are known, which diol compounds include ethylene diol, propanediols, butanediols, diethylene glycol, dipropylene glycol, and neopentylglycol and the like (see Patent Documents 8-18). As components of a fountain solution composition, 2-ethyl-1,3-hexanediol, and 1,5-pentanediol have been disclosed (see Patent Documents 11, 13 and 15). Further, compounds such as 1,5-pentane diol, 2,4-pentane diol, 2,5-hexane diol, 1,6-hexane diol, 1,7-heptane diol, 2,4-heptane diol, 2-methyl 2,4-pentane diol, 2-ethyl 1,3-hexane diol, 1,8-octanediol, 1,9-nonane diol, 1,10-decane diol, pinacol, cyclopentane 1,2-diol, cyclohexane 1,2-diol, cyclohexane 1,4-diol, 2,2-diethyl 1,3-propanediol, and 2-butyl 2-ethyl 1,3-propanediol have been suggested as possible fountain solution components (see Patent Document 19).

However, a method for improving blanket piling is not explicitly mentioned in the above prior arts.
[Patent Document 1] JP 2006-328299 A
[Patent Document 2] JP 2006-322114 A
[Patent Document 3] JP 2001-138655 A
[Patent Document 4] JP 2007-50665 A
[Patent Document 5] JP 2007-168124 A
[Patent Document 6] JP 2007-55182 A
[Patent Document 7] JP S61-189997 A
[Patent Document 8] JP H5-221179 A
[Patent Document 9] JP H5-221180 A
[Patent Document 10] JP 2001-232926 A
[Patent Document 11] JP H10-181234 A
[Patent Document 12] JP 2005-246918 A
[Patent Document 13] JP H6-191175 A
[Patent Document 14] JP 2006-321089 A
[Patent Document 15] JP 2000-280645 A
[Patent Document 16] JP 2002-283766 A
[Patent Document 17] JP H5-139068 A
[Patent Document 18] JP 2004-322406 A
[Patent Document 19] JP H2-48996 A

### DISCLOSURE OF THE INVENTION

### Problem to be Solved by the Invention

An object of the present invention is to provide a method for improving blanket piling, and in particular to provide a method for improving blanket piling in terms of fountain solution compositions.

### Means to Solve the Problem

In order to achieve the objects described above, the present inventor extensively studied to discover that blanket piling is significantly improved by adding particular diol compounds to a fountain solution.

Accordingly, the present invention is a fountain solution composition for lithographic printing characterized by comprising at least one acyclic hydrocarbon diol compound, having 6 to 8 carbon atoms in total and two —OH groups, wherein said two —OH groups bind to carbon atoms at 1- and 2-positions, respectively.

In one embodiment of the invention, the diol compound is 1,2-octanediol.

In another embodiment of the fountain solution composition of the invention, the fountain solution composition as described above further comprises at least one compound of formula (I) shown below, and at least one compound of formula (II) shown below.

R¹—O—(CH₂CHR²O)ₘ—H (I)

where R¹ represents an alkyl group having 1 to 4 carbon atoms, R² represents a hydrogen atom or methyl group, and m represents an integer of 1 to 3.

HO—(CH₂CH(CH₃)O)ₙ—H (II)

where n represents an integer of 1 to 5.

In one embodiment of the fountain solution composition of the invention, the composition comprises the acyclic hydrocarbon diol compound, described above, at least one compound of above formula (I), and at least one compound of above formula (II), but does not contain a water-soluble polymer compound.

In yet another embodiment of the fountain solution composition of the invention, the fountain solution composition described above further comprises at least one compound selected from an adduct compound of ethylene oxide and propylene oxide to ethylenediamine and an adduct compound of ethylene oxide and propylene oxide to diethylenetriamine. In embodiments where the fountain solution composition of the invention comprises at least one compounds selected from an adduct compound of ethylene oxide and propylene oxide to ethylenediamine and an adduct compound of ethylene oxide and propylene oxide to diethylenetriamine, it is preferable that the fountain solution composition of the invention further comprises a water-soluble polymer compound.

In yet another embodiment of the fountain solution composition of the invention, the fountain solution composition described above further comprises a pyrrolidone derivative represented by the following general formula (VI):

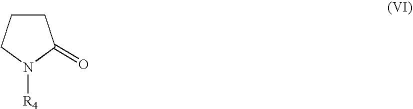

wherein R₄ represents an alkyl group having 2 to 12 carbon atoms.

In yet another embodiment of the fountain solution composition of the invention, the fountain solution composition described above further comprises at least one selected from the group consisting of acetylene glycols, acetylene alcohols, and an adduct compound of ethylene oxide and/or propylene oxide thereto. As one specific embodiment thereof, there is the fountain solution composition comprising at least one compound selected from the group consisting of 3,6-dimethyl-4-octyne-3,6-diol, 2,4,7,9-tetramethyl-5-decyne-4,7-diol, and an adduct compound of 4 to 10 ethylene oxides to 2,4,7,9-tetramethyl-5-decyne-4,7-diol.

The fountain solution composition of the invention can preferably be used for rotary heat-set offset printing, hence, the present invention is also directed to a rotary heat-set offset printing process using an ink for rotary offset of a heat-set type and the above fountain solution composition.

### Effect of the Invention

The fountain solution composition of the invention represses the occurrence of blanket piling, and stably produces printings with high quality even through a continuous printing operation for a long period of time. In addition, the fountain solution composition of the invention does not require the use of volatile organic solvents such as isopropyl alcohol, which has been conventionally used for fountain solution. Therefore, by using the fountain solution composition of the invention, the amount of the fountain solution to be supplied can easily be controlled, and the ink-stain (ink feedback) on the dampening roller hardly deteriorates, so that an excellent printing performance would be provided. In addition, the fountain solution composition of the invention is more favorable for the operational environment.

### BEST MODE FOR CARRYING OUT THE INVENTION

The present invention will be described in its detail below.

A diol compound used for the present invention is an acyclic hydrocarbon diol compound, having 6-8 carbon atoms in total, and 2 —OH groups each of which binds to 1- or 2-position of a carbon atom, respectively.

Compounds having not more than 5 carbon atoms hardly exhibit the effect intended by the invention, whereas compounds having not less than 10 carbon atoms show poor solubility so that the effect intended by the invention would not be observed. Compounds other than those in which two —OH groups bind to 1- and 2-positions of carbon atoms, respectively, such as 1,3-octanediol and 1,8-octanediol, do not have the effect intended by the present invention. Thus, it was observed that only compounds having hydrophilicity-hydrophobicity balances and molecular structures within narrow limits could exhibit the effect aimed by the invention.

For the fountain solution composition of the invention, two or more diol compounds can be used in combination.

An appropriate amount of the diol compound of the invention to be added is 0.05 to 1.0% by weight based on the total amount of the fountain solution composition when used, because within the above range, the composition would exhibit the effect of the invention sufficiently, while not displaying poor solubility or causing ink-stain (ink feedback) on the dampening roller. The amount to be added is, preferably 0.1 to 0.7% by weight, and more preferably 0.2 to 0.5% by weight.

It is preferable that the fountain solution composition would be generally used by diluting a concentrated solution before use in terms of transportation cost, storage space, and production cost including the cost of packaging materials. The dilution rate is preferably 10 to 200 fold, more preferably 20 to 150 fold, and the most preferably 30 to 100 fold. Therefore, the concentration of the composition in the concentrated solution is adjusted to a level which would give the above concentration of the fountain solution composition of use upon dilution. Higher concentration is preferred in respect of cost, however, excessive levels of concentration may cause some problems such as deposition or liquid separation, therefore being not favorable.

Upon preparation of the concentrated solution, as a solubilizing agent, it is preferred to use at least one compound of formula (I) below and at least one compound of formula (II) below, and these compounds would enhance the effect of the invention in a synergistic manner.

### Compound of Formula (I)

R¹—O—(CH₂CHR²O)ₘ—H (I)

where R¹ represents an alkyl group having 1 to 4 carbon atoms, R² represents a hydrogen atom or methyl group, and m represents an integer of 1 to 3.

In the compound of formula (I), in particular, R¹ represents a linear or branched alkyl group having 1 to 4 carbon atoms including, in particular, methyl, ethyl, propyl, isopropyl, n-butyl, isobutyl, and t-butyl groups, among which an n-butyl or t-butyl group is especially preferred because these increase solubility of diol compounds and repress blanket piling. R² represents a hydrogen atom or a methyl group, preferably a methyl group, and m represents an integer of 1 to 3, preferably 1.

Examples of the compound of formula (I) include ethylene glycol mono t-butyl ether, ethylene glycol mono n-butyl ether, propylene glycol monomethyl ether, dipropylene glycol monomethyl ether, tripropylene glycol monomethyl ether, propylene glycol monoethyl ether, dipropylene glycol monoethyl ether, tripropylene glycol monoethyl ether, tetrapropylene glycol monoethyl ether, propylene glycol monopropyl ether, dipropylene glycol monopropyl ether, tripropylene glycol monopropyl ether, propylene glycol monoisopropyl ether, dipropylene glycol monoisopropyl ether, tripropylene glycol monoisopropyl ether, propylene glycol mono n-butyl ether, dipropylene glycol monobutyl ether, tripropylene glycol monobutyl ether, propylene glycol monoisobutyl ether, dipropylene glycol monoisobutyl ether, tripropylene glycol monoisobutyl ether, propylene glycol mono t-butyl ether, dipropylene glycol mono t-butyl ether and tripropylene glycol mono t-butyl ether.

These compounds can be used either alone or in combination of more than one.

Among these, n-butyl or t-butyl ether of propylene glycol or ethylene glycol can be preferably used. An appropriate amount of the compound of formula (I) to be added is 0.05 to 5.0% by weight based on the total amount of the fountain solution composition when used, because within the above range, the composition would exhibit a sufficient effect of blanket piling repression, while not causing problems such as roller stripping or poor printing durability. More preferably, the amount to be added is 0.1 to 3.0% by weight.

### Compound of Formula (II)

HO—(CH₂CH(CH₃)O)ₙ—H (II)

where n represents an integer of 1 to 5.

In the compound of formula (II), in particular, n is preferably 1.

Accordingly, examples of the compound of formula (II) include propylene glycol, dipropylene glycol, tripropyleneglycol, tetrapropylene glycol and pentapropylene glycol. These compounds can be used either alone or in combination of more than one. Among these compounds, propylene glycol, dipyropylene glycol, and tripropylene glycol are preferable, and propylene glycol is the most preferable in order to increase diol compound solubility.

An appropriate content of the compound of formula (II) in a fountain solution composition is 0.05 to 5.0% by weight based on the total amount of the fountain solution composition when used, because within the above range, the solubility of the diol compound becomes sufficient, and the composition would exhibit a sufficient effect of blanket piling repression, while not causing roller stripping due to stabilized ink concentration. More preferably, the amount to be added is 0.1 to 3.0% by weight.

The fountain solution composition of the invention can further comprise at least one compound selected from an adduct compound of ethylene oxide and propylene oxide to ethylenediamine and an adduct compound of ethylene oxide and propylene oxide to diethylenetriamine.

These compounds will be described as follows.

### [Adduct Compound of Ethylene Oxide and Propylene Oxide to Ethylenediamine]

An adduct compound of ethylene oxide and propylene oxide to ethylenediamine used for the invention has an appropriate weight-average molecular weight of 500 to 20000, preferably 500 to 5000, more preferably 800 to 1500, and most preferably about 1000.

In the compound, a molar ratio of attachment of ethylene oxide and propylene oxide is suitably in the range of 5:95 to 50:50, and more preferably in the range of 20:80 to 35:65 in terms of sufficient printing performance.

Bond-structures of ethylene oxide and propylene oxide in the compound include a block structure in which ethylene oxide is added first followed by propylene oxide, block structure in which propylene oxide is added first followed by ethylene oxide, and random structure in which ethylene oxide and propylene oxide are added simultaneously, however, any of these structures displays almost the same effect.

used for the invention can be produced by a conventional method, for example, by allowing ethylene oxide and/or propylene oxide to react with ethylenediamine in the presence of a catalyst.

The adduct compound of ethylene oxide and propylene oxide to ethylenediamine used for the invention is represented by formula (III) as follows.

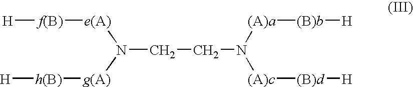

where A and B each independently represents —CH₂CH₂— or CH₂CH(CH₃)O—, A and B are different groups from each other, a to h each represents an integer of 0 to 50, wherein at least one of a, c, e and g is not less than 1, and at least one of b, d, f and h is not less than 1. The symbols a to h take certain values so that the molecular weight of the compound in total would be 500 to 20000. Each copolymer chain may be in either a block or random structure.

The molecular weight of the compound and the ratio of ethylene oxide and propylene oxide can be determined, for example, by measuring a hydroxyl value and an amine value, or by NMR measurement.

The compound of formula (III) is preferably represented by formula (IV) as follows.

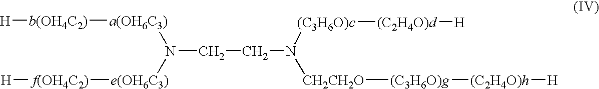

where a, b, c, d, e, f, g and h each represents an integer of 0 to 50, wherein at least one of a, c, e and g is not less than 1, and at least one of b, d, f and h is not less than 1.

The compound of above formula (IV) suitably has a weight-average molecular weight of 500 to 20000, preferably 500 to 5000, and more preferably 800 to 1500. The symbols a to h take certain values so that the molecular weight of the compound in total would be 500 to 20000, however, a to h are preferably 1 to 10, and in particular, 2 to 4.

Such compounds would not adversely affect image areas, even when the remaining water drops are left and becomes concentrated by evaporation during run-down time of the printing machine. These compounds can take the place of isopropyl alcohol without being combined with volatile organic solvents, however, tend to deteriorate blanket piling and ink-stain (ink feedback) on the dampening roller. By combining with the diol compound used for the invention, the above compound would be able to take place of isopropyl alcohol without aggravating blanket piling and ink-stain (ink feedback) on the dampening roller.

In the compound, a suitable molar ratio of added ethylene oxide and added propylene oxide is suitably in the range of 5:95 to 50:50, and more preferably in the range of 20:80 to 35:65 in terms of sufficient printing performance.

### Adduct Compound of ethylene oxide and propylene oxide to diethylenetriamine

An adduct compound of ethylene oxide and propylene oxide to diethylenetriamine used for the invention has an appropriate weight-average molecular weight of 500 to 3000, preferably 800 to 2000, and most preferably about 1000.

Compounds having such molecular weights would not adversely affect image areas, even when the remaining water drops are left and becomes concentrated by evaporation during run-down time of the printing machine. These compounds can take place of isopropyl alcohol without being combined with volatile organic solvents.

In the compound, a suitable molar ratio of added ethylene oxide and added propylene oxide is suitably in the range of 5:95 to 50:50, and more preferably in the range of 20:80 to 35:65 in terms of sufficient printing performance.

Bond-structures of ethylene oxide and propylene oxide include a block structure in which ethylene oxide is attached first followed by propylene oxide, block structure in which propylene oxide is attached first followed by ethylene oxide, and random structure in which ethylene oxide and propylene oxide are attached simultaneously, however, any of these structures displays almost the same effect.

The adduct compound of ethylene oxide and propylene oxide to diethylenetriamine used for the invention can be produced by a conventional method, for example, by allowing ethylene oxide and/or propylene oxide to react with diethylenetriamine in the presence of a catalyst. Alternatively, one can cool diethylenetriamine along with acetonitrile in an ice bath and add propylene oxide thereto, and further add ethylene oxide thereto to allow to react, then remove the deposit from the mixture by filtration, whereby obtain the adduct compound of propylene oxide/ethylene oxide to diethylenetriamine.

The adduct compound of propylene oxide/ethylene oxide to diethylenetriamine used for the invention is specifically represented by formula (V) as follows.

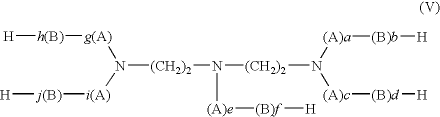

where A and B each independently represents —CH₂CH₂O— or —CH₂CH(CH₃)O—, A and B are different groups from each other, a to j each represents an integer not less than 1. Each copolymer chain may be in either a block or random structure. In the formula, the symbols a to j take certain values so that the molecular weight of the compound in total would be 500 to 3000, however, a to h are preferably 1 to 6, and in particular, 2 to 3.

The molecular weight of the compound and the ratio of ethylene oxide and propylene oxide can be determined, for example, by measuring a hydroxyl value and an amine value or by NMR measurement.

Isopropyl alcohol can be replaced by the above compound contained in an amount of 0.01 to 1% by weight, preferably 0.05 to 0.5% by weight, in a fountain solution composition when used, and then an excellent printability would be displayed. Such compounds would not adversely affect image areas, even when the remaining water drops are left and becomes concentrated by evaporation during run-down time of the printing machine after using the fountain solution. However, these compounds tend to deteriorate blanket piling and ink-stain (ink feedback) on the dampening roller. By combining with the diol compound used for the invention, the above compound would be able to take the place of isopropyl alcohol without aggravating blanket piling and ink-stain (ink feedback) on the dampening roller.

In the case the fountain solution composition of the invention includes at least one of the compounds of above formula (III), (IV) or (V), an addition of a water-soluble polymer compound described below to the composition would be effective for suppressing blanket piling. When the fountain solution composition does not include the compounds of above formula (III), (IV) or (V), avoiding addition of a water-soluble compound would be rather effective for suppressing blanket piling.

The fountain solution composition of the invention may include other components as follows:
(a) auxiliary agent for wettability improvement
(b) water-soluble polymer compound
(c) pH adjusting agent
(d) chelating agent
(e) odor masking agent
(f) others ((i) preservatives, (ii) colorant, (iii) anticorrosives, (iv) antifoaming agent, etc.)

As for (a) auxiliary agents for wettability improvement, surfactants and other solvents can be used. Among surfactants, for example, anionic surfactants include fatty acid salts, abietate, hydroxyalkanesulfonate, alkanesulfonate, dialkyl sulfosuccinate, linear alkylbenzene sulfonate, branched alkylbenzene sulfonate, alkylnaphthalenesulfonate, alkylphenoxy polyoxyethylene propylsulfonate, polyoxyethylene alkylsulfenyl ether salt, N-methyl-N-oleyl taurine sodium salt, N-alkyl sulfosuccinic acid monoamide disodium salt, petroleum sulfonate, sulfated castor oil, sulfated beef tallow oil, sulfuric ester salt of fatty acid alkyl ester, alkyl sulfuric acid ester salt, polyoxyethylene alkyl ether sulfuric ester salt, fatty acid monoglyceride sulfuric ester salt, polyoxyethylene alkylphenyl ether sulfuric ester salt, polyoxyethylene styrylphenyl ether sulfuric ester salt, alkyl phosphoric ester salt, polyoxyethylene alkyl ether phosphoric ester salt, polyoxyethylene alkylphenyl ether phosphoric ester salt, partially saponified product of styrene-maleic anhydride copolymer, partially saponified product of olefin-maleic anhydride copolymer, naphthalene sulfonate formalin condensate and the like. Among these, dialkyl sulfosuccinate, alkyl sulfuric acid ester salt and alkylnaphthalenesulfonate are particularly preferably used.

Nonionic surfactants include polyoxyethylene alkyl ether, polyoxyethylene alkylphenyl ether, polyoxyethylene polystyrylphenyl ether, polyoxyethylene polyoxypropylene alkyl ether, glycerol fatty acid partial ester, sorbitan fatty acid partial ester, pentaerythritol fatty acid partial ester, propylene glycol mono fatty acid ester, sucrose fatty acid partial ester, polyoxyethylene sorbitan fatty acid partial ester, polyoxyethylene sorbitol fatty acid partial ester, polyethylene glycol fatty acid ester, polyglycerin fatty acid partial ester, polyoxyethylenated castor oil, polyoxyethylene glycerol fatty acid partial ester, fatty acid diethanol amide, N,N-bis-2-hydroxy alkylamine, polyoxyethylene alkylamine, triethanolamine fatty acid ester, trialkylamine oxide and the like. In addition, fluorochemical surfactants and silicon surfactants may be used. Among these, polyoxyethylene alkylphenyl ether and polyoxyethylene-polyoxypropylene block polymer are preferably used. In addition, there are surfactants of silicon derivatives and fluorine derivatives. In case of using a surfactant, an appropriate content thereof is not more than 1.0% by weight, preferably 0.001 to 0.5% by weight in the fountain solution composition when used, in view of foaming. In addition, combination of two or more surfactants can be employed.

As for another auxiliary agent or wetting solvent, 3-methoxy-3-methyl butanol, 3-methoxybutanol, ethylene glycol, diethylene glycol, triethylene glycol, butylene glycol, hexylene glycol, glycerol, diglycerol, polyglycerin, trimethylolpropane and the like can be used. These solvents can be used either alone or in combination of more than one. These solvents are appropriately used in a range of 0.1 to 3% by weight based on the total weight of the fountain solution composition when used, and preferably 0.3 to 2% by weight.

As for another auxiliary agent, a pyrrolidone derivative represented by the following general formula (VI) may be used.

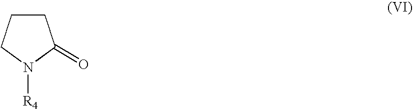

wherein R₄ represents an alkyl group having 2 to 12 carbon atoms.

Specific examples of the pyrrolidone derivative include ethyl pyrrolidone, butyl pyrrolidone, pentapyrrolidone, hexapyrrolidone, octylpyrrolidone, laurylpyrrolidone and the like. These compounds can be used either alone or in combination of more than one. Among these, those wherein R₄ represents an alkyl having 6 or more carbon atoms in the formula (VI) are preferable, and octylpyrrolidone is particularly preferable. The compound represented by the general formula (VI) are used appropriately in an amount of 0.0001 to 1.0% by weight on the basis of the total weight of the fountain solution composition when used, and more preferably 0.001 to 0.1% by weight.

The fountain solution composition of the invention can also comprise at least one selected from the group consisting of acetylene glycols, acetylene alcohols, and an adduct compound of ethylene oxide and/or propylene oxide thereto. Specific examples of said compounds include 3,5-dimethyl-1-hexyne-3-ol, 2,5-dimethyl-3-hexyne-2,5-diol, 2,4,7,9-tetramethyl-5-decyne-4,7-diol, 3,6-dimethyl-4-octyne-3,6-diol, 2-butyne-1,4-diol, 3-methyl-1-butyne-3-ol, an adduct compound of ethylene oxide and/or propylene oxide to the above compound, and the like. Among these, 3,6-dimethyl-4-octyne-3,6-diol, 2,4,7,9-tetramethyl-5-decyne-4,7-diol, and an adduct compound of 4 to 10 ethylene oxides to 2,4,7,9-tetramethyl-5-decyne-4,7-diol are preferable. These compounds are used appropriately in an amount of 0.0001 to 1% by weight on the basis of the total weight of the fountain solution composition when used, and more preferably 0.001 to 0.1% by weight.

The following compounds can be added to the fountain solution composition, if desired, for the purpose of adjustment of dynamic surface tension, solubilization, control on a mix rate (emulsification rate) of printing ink into a proper range, or the like: 2-ethyl-1,3-hexanediol, an adduct compound of ethylene oxide and/or propylene oxide to 2-ethyl-1,3-hexanediol, an adduct compound of propylene oxide to trimethylolpropane, an adduct compound of propylene oxide to glycerin, an adduct compound of propylene oxide to sorbitol, tetrahydrofurfuryl alcohol, and the like. Among these, preferred as an auxiliary agent for adjustment of dynamic surface tension is 2-ethyl-1,3-hexanediol, and preferred as an agent for solubilization is tetrahydrofurfuryl alcohol. As an agent for controlling an ink emulsification rate, an adduct compound of ethylene oxide to 2-ethyl-1,3-hexanediol, an adduct compound of propylene oxide to trimethylolpropane and the like may be preferably used. These compounds can be used either alone or in combination of more than one. These compounds are used appropriately in an amount of 0.01 to 7% by weight on the basis of the total weight of the fountain solution composition when used, and more preferably 0.05 to 5% by weight.

The water-soluble polymer compounds (b) used for the fountain solution composition of the invention include natural products and denatured products thereof such as gum Arabic, starch derivatives (e.g. dextrin, enzymolysis dextrin, hydroxypropylated enzymolysis dextrin, carboxymethylated starch, phosphoric acid starch, octenylsuccinated starch), alginate, cellulose derivatives (e.g. carboxymethyl cellulose, carboxyethyl cellulose, methyl cellulose, hydroxypropyl cellulose, hydroxypropylmethyl cellulose, hydroxyethyl cellulose) and the like, and synthetic products such as polyethylene glycol and copolymers thereof, polyvinyl alcohol and derivatives thereof, polyvinylpyrrolidone, polyacrylamide and copolymers thereof, polyacrylic acid and copolymers thereof, a vinyl methyl ether/maleic anhydride copolymer, a vinyl acetate/maleic anhydride copolymer, polystyrene sulfonic acid and copolymers thereof, and the like. The appropriate content of the water-soluble polymer is 0.0001 to 0.1% by weight, preferably 0.0005 to 0.05% by weight, based on the total weight of the fountain solution composition when used.

Among the water-soluble polymer compounds listed above, polyvinylpyrrolidone, hydroxypropyl cellulose, and hydroxypropylmethyl cellulose are preferably used for the invention.

Polyvinylpyrrolidone contained in the fountain solution composition refers to a homopolymer of vinylpyrrolidone. Suitably, the molecular weight of polyvinylpyrrolidone is 200 to 3,000,000, preferably 300 to 500,000, and more preferably 300 to 100,000. The molecular weight of 300 to 30,000 is particularly preferred.

These polyvinylpyrrolidone can be used either alone or in combination of more than one with different molecular weights. In addition, they can be combined with polyvinylpyrrolidone of low molecular weight, such as vinylpyrrolidone oligomers with degree of polymerization of 3 to 5.

Such polyvinylpyrrolidone is commercially available. For example, polyvinylpyrrolidone in different grades, such as K-15, K-30, K-60, K-90, K-120 and the like from ISP Co., Ltd. can be usefully employed.

The appropriate polyvinylpyrrolidone content in the fountain solution composition when used is 0.001 to 0.3% by weight, and preferably 0.005 to 0.2% by weight.

The fountain solution composition of the invention preferably comprises at least one compound selected from sugars. The sugar for use can be selected from monosaccharide, disaccharide, oligosaccharide and sugar alcohols thereof obtainable by hydrogenation. Examples of sugars include D-erythrose, D-threose, D-arabinose, D-ribose, D-xylose, D-erythro-pentulose, D-allulose, D-galactose, D-glucose, D-mannose, D-talose, β-D-fructose, α-L-sorbose, 6-deoxy-D-glucose, D-glycero-D-galactose, α-D-allulo-heptulose, β-D-altro-3-heptulose, saccharose, lactose, D-maltose, isomaltose, inulobiose, maltotriose, D,L-arabite, ribitol, xylitol, D,L-sorbitol, D,L-mannite, D,L-idit, D,L-talite, dulcite, allodulcite, maltitol, reduced starch syrup and the like. These sugars can be used either alone or in combination of more than one.

The appropriate content of at least one compound selected from sugars is 0.01 to 1% by weight, and preferably 0.1 to 0.8% by weight, in the fountain solution composition when used.

Water-soluble organic and/or inorganic acids and/or salts thereof can be used as pH adjusting agents (c) used for the fountain solution composition of the invention. These compounds act as a pH adjusting agent or buffer in the fountain solution and can be effectively used for adequate etching or anticorrosive treatment. Preferable organic acid includes, for example, citric acid, ascorbic acid, malic acid, tartaric acid, lactic acid, acetic acid, gluconic acid, acetic acid, hydroxyacetic acid, oxalic acid, malonic acid, levulinic acid, sulfanilic acid, p-toluenesulfonic acid, phytic acid, an organic phosphonic acid and the like. Inorganic acid includes phosphoric acid, nitric acid, sulfuric acid, polyphosphoric acid and the like. In addition, alkali metal salts, alkaline earth metal salts, ammonium salts or organic amine salts of these organic and/or inorganic acids can be preferably used, and such organic and inorganic acids and salts thereof can be used either alone or in combination of more than one. The amount of such a pH adjusting agent to be added to the fountain solution composition of the invention is preferably in the range of 0.001 to 0.3% by weight. Although the pH adjusting agent is preferably used within an acidic condition of pH 3-7 in the fountain solution composition, it can also be used within alkali condition of pH7-11 in the presence of alkali metal hydroxide, phosphoric acid, alkali metal salt, alkali metal salt of carbonic acid, silicate and the like.

The fountain solution composition of the invention may further comprise a chelating agent (d). A fountain solution composition is usually prepared by diluting the concentrated solution with tap water, well water or the like, and components of tap water or well water such as calcium ion may adversely affect printing and make printing matter stain-prone. Under such condition, addition of a chelating agent may solve the above problem. Examples of preferred chelating agents include ethylenediaminetetraacetic acid and potassium salts and sodium salts thereof; diethylenetriaminepentaacetic acid and potassium salts and sodium salts thereof; triethylenetetraminehexaacetic acid and potassium salts and sodium salts thereof; hydroxyethylethylenediaminetriacetic acid and potassium salts and sodium salts thereof; nitrilotriacetic acid and sodium salts thereof; organic phosphonic acids such as 1-hydroxy ethane-1,1-diphosphonic acid and potassium salts and sodium salts thereof; aminotri(methylenephosphonic acid) and potassium salts and sodium salts thereof, and phosphonoalkanetricarboxylic acids. Organic amine salts are also effective instead of the sodium salts or potassium salts of the chelating agents above. Among these, chelating agents which are stable in the fountain solution composition when used and do not inhibit printing property are selected. The appropriate content of the chelating agent is 0.001 to 0.5% by weight, and preferably 0.002 to 0.25% by weight in the fountain solution composition when used.

Odor masking agents (e) include esters which is conventionally known to be used as flavors. Examples of odor masking agents include those represented by formula (VII) as follows.

R²—COOR³ (VII)

In the compound of formula (VII), R² is a C₁-C₁₅ alkyl, alkenyl or aralkyl group or phenyl group; in case where R² is alkyl or alkenyl, the number of carbon atoms therein is preferably 4 to 8; in case where R² represents an alkyl, alkenyl or aralkyl group, the group may be either linear or branched. Note that a suitable alkenyl group has one double bond. Aralkyl groups include a benzyl group, phenylethyl group and the like. One or more of hydrogen atoms of alkyl, alkenyl or aralkyl group or phenyl group represented by R² may optionally be substituted by hydroxy or acetyl groups. R³ is a C₃-C₁₀ alkyl, aralkyl or phenyl group, and may be either linear or branched; in case where R³ is an alkyl group, the number of carbon atoms therein is preferably from 3 to 9. Aralkyl groups include a benzyl group, phenylethyl group and the like.

Specific examples of odor masking agents (e) which may be used include esters of formic acid, acetic acid, propionic acid, butyric acid, isobutyric acid, 2-ethylbutyric acid, valeric acid, isovaleric acid, 2-methylvaleric acid, hexanoic acid (caproic acid), 4-methylpentanoic acid (isohexane acid), 2-hexenoic acid, 4-pentene acid, heptanoic acid, 2-methylheptane acid, octanoic acid (caprylic acid), nonanoic acid, decanoic acid (capric acid), 2-decenoic acid, lauric acid or myristic acid. In addition, odor masking agents also includes acetoacetic esters such as benzyl phenylacetate, ethyl acetoacetate and 2-hexyl acetoacetate. Among these, n-pentyl acetate, isopentyl acetate, n-butyl butyrate, n-pentyl butyrate and isopentyl butyrate are preferred and, in particular, n-butyl butyrate, n-pentyl butyrate and isopentyl butyrate are preferred. The appropriate content of such acid ester in the fountain solution composition is 0.0001 to 10% by weight, and preferably 0.001 to 1% by weight, based on the total weight of the fountain solution composition when used. Such odor masking agents may improve the working environment, and be used in combination with vanillin, ethyl vanillin and the like.

Preservatives (f)(i) used for the fountain solution composition of the invention include phenol or derivatives thereof, formalin, imidazole derivatives, sodium dehydroacetate, 4-isothiazolin-3-one derivatives, benztriazole derivatives, derivatives of amidine or guanidine, quaternary ammonium salt, pyridine, derivatives of quinoline or guanidine, derivatives of diazine or triazole, derivatives of oxazol or oxazin, bromonitro alcohols such as bromonitro propanol, 2,2-dibromo-2-nitro ethanol, 3-bromo-3-nitro pentane 2,4-diol, and the like. Preferable amount of the preservative to be added is such that stably exhibit its effect on bacteria, fungi, yeasts and the like, and varies with the types of the bacteria, fungi and yeasts, however, it is preferably 0.001 to 1.0% by weight relative to the fountain solution composition when used. It is also preferable to use preservatives in combination of more than one which are potent against a variety of bacteria, fungi and yeasts.

Food colorings and the like can be preferably used for invention as colorants (f)(ii). Examples of colorants include CI No. 19140 and 15985 for yellow pigments; CI No. 16185, 45430, 16255, 45380, and 45100 for red pigments; CI No. 42640 for purple pigment; CI No. 42090 and 73015 for blue pigment; CI No. 42095 for green pigment; and the like. Anticorrosives (f)(iii) which may be used for the invention include benzotriazole, 5-methylbenzotriazol, thiosalicylic acid, benzimidazole and derivatives thereof and the like. Silicone antifoaming agents are preferable for antifoaming agents (f)(iv) which may be used for the invention. Among these, either emulsion-dispersing type or solubilized type may be used.

The balance of the fountain solution composition according to the invention is water. Fountain solution compositions are generally concentrated in commercial products on a commercial basis. Accordingly, the concentrated solution can be obtained as an aqueous solution with the above components dissolved therein by using water, preferably desalted water, i.e. pure water. The concentrated solution is used by diluting about 10-200 fold with tap water, well water or the like thereby making the fountain solution composition when used.

The fountain solution composition of the invention can be used for a variety of lithographic printing plates, and, in particular, can be preferably used for lithographic printing plates which can be obtained by imagewise exposure and development of a photo-sensitive lithographic printing plate (a printing plate which is preliminarily photosensitized and referred to as PS plate) onto the surface of an aluminum plate support. Preferable examples of such PS plates include a plate in which a photo-sensitive layer consisting of a mixture with diazo resin (salt of a condensation product of p-diazodiphenylamine and paraformaldehyde) and shellac is prepared on an aluminium plate as described in GB Patent No. 1, 350, 521, a plate in which a photo-sensitive layer consisting of a mixture with diazo resin and a polymer containing hydroxyethylmethacrylate unit or hydroxyethyl acrylate unit as the primary recurring unit is prepared on an aluminium plate as described in GB Patent Nos. 1, 460, 978 and 1, 505, 739, a negative-working PS plate in which a photo-sensitive polymer containing dimethylmaleimide group is prepared on an aluminium plate as described in JP H2-236552 A and JP H4-274429 A, and a positive-working PS plate in which a photo-sensitive polymer consisting of a mixture with o-quinonediazido photosensitive product and novolac phenol resin is prepared on an aluminium plate as described in JP S50-125806 A. Furthermore, the fountain solution composition can be used for burning-treated positive-working PS plates.

In the composition forming the above photosensitive layer, an alkali-soluble resin other than the alkali-soluble novolac resin may be incorporated, if necessary. Such an alkali-soluble resin includes for example, styrene-acrylic acid copolymer, methylmethacrylate-mathacrylic acid copolymer, alkali-soluble polyurethane resin, alkali-soluble vinyl resin as disclosed in J.P. KOKOKU (publication of examined application) No. Sho 52-28401, and alkali-soluble polybutyral resin. Further, a PS plate wherein a photosensitive layer of photopolymerizable photopolymer composition is provided on an aluminum plate as disclosed in U.S. Pat. Nos. 4,072,528 and 4,072,527, and a PS plate wherein a photosensitive layer comprising a mixture of an azide compound and a water-soluble polymer is provided on an aluminum plate as disclosed in GB Patent Nos. 1,235,281 and 1,495,861 are preferable.

Furthermore, the fountain solution composition of the present invention can be preferably applied to a CTP plate, which has been directly exposed by a visible or infrared laser, and examples thereof include a photopolymer type digital plate such as LP-NX manufactured by FUJI FILM Corporation, a thermal positive type digital plate such as LH-PI manufactured by FUJI FILM Corporation, a plate of on press processing type to be developed by a fountain solution and an ink, such as ET-S manufactured by FUJI FILM Corporation, and a thermal negative type digital plate such as LH-NI manufactured by FUJI FILM Corporation, and the like.

### EXAMPLES

The present invention will now be described more in detail by way of examples thereof. It should be noted that % used herein indicates % by weight unless otherwise mentioned.

### Examples 1 and 2 and Comparative Examples 1-11

A variety of fountain solution compositions were prepared according to the following preparation in the same manner, except for changing diol compounds as shown in Table 1 below, but using the equal weight thereof. The units used in the preparation is in grams, and each value represents an amount added when water was finally added up to 100 grams, therefore consistent with % by weight.

Formulation of the fountain solution composition (working solution) of use

| Ingredients | Additive amount | |
|---|---|---|
| Propylene glycol mono-n-butyl ether | 0.5 | g |
| Propylene glycol | 0.3 | g |
| Diol compounds shown in Table 1 | 0.3 | g |
| Ammonium nitrate | 0.05 | g |
| Citric acid | 0.01 | g |
| Isothiazolin-3-one | 0.002 | g |
| Benzotriazole | 0.001 | g |
| Water | up to 100 | g in total |

The following assays were conducted for each fountain solution composition after printing 20000 copies using Lithron26 printing machine from KOMORI Corporation with an ink: Super LeoEcoo Black L, TOYO INK MFG CO., LTD., ultra lightweight coat papers: OK coat from OJI Paper Co., Ltd., and a plate: PN-V from FUJI FILM Corporation.

### (1) Evaluation of Blanket Piling

After above printing, the blanket was removed and the height of deposit on an non-image area was measured with a stylus surface roughness meter (SURFCORDER) to evaluate blanket piling as a relative value to diol compound free fountain solution. The smaller the value is, the smaller the height of piling is, therefore preferable.

### (2) Reduction Ratio of Dot Values

Dot values in an image area with a dot value of 40% were measured for the printed matters at starting point and ending point of the printing of 20000 copies using a reflection density meter D19C from Gretag Macbeth thereby calculating the reduction ratio of dot values at the ending point of printing over the starting point.

Reduction ratio=(dot value at starting point−dot value at ending point)/dot value at starting point×100

The smaller values indicate that the printing is performed more stably, therefore are preferable.

### (3) Ink-Stain (Ink Feedback) on the Dampening Roller

After completion of the printing, ink-stain on the dampening roller were visually observed and ranked as follows

◯ . . . little ink-stain
Δ . . . slight ink-stain
× . . . obvious ink-stain

The results are shown in Table 1.

TABLE 1

| | | | | Reduction | Ink-stain | |
|---|---|---|---|---|---|---|
| | | | | ratio of | on | |
| | | | Blanket | dot value | dampening | |
| Examples | | Diol compound | piling | (%) | roller | Remarks |
| Example | 1 | 1,2-hexanediol | 67 | 12 | ◯ | |
| | 2 | 1,2-octanediol | 49 | 6 | ◯ | |
| Comparative Example | 1 | No additive | 100 | 30 | ◯ | |
| | 2 | 1,2-butanediol | 98 | 31 | ◯ | |
| | 3 | 1,2-pentanediol | 96 | 29 | ◯ | |
| | 4 | 1,2-decanediol | 94 | 27 | Δ | poor |
| | | | | | | solubility |
| | 5 | 1,2-dodecanediol | 98 | 29 | Δ | poor |
| | | | | | | solubility |
| | 6 | 1,3-octanediol | 100 | 29 | ◯ | |
| | 7 | 1,8-octanediol | 97 | 30 | Δ | |
| | 8 | 1,9-nonanediol | 100 | 32 | X | |
| | 9 | 1,3-decanediol | 98 | 28 | X | poor |
| | | | | | | solubility |
| | 10 | 1,10-decanediol | 96 | 29 | X | poor |
| | | | | | | solubility |
| | 11 | 1,3-dodecanediol | 97 | 28 | X | poor |
| | | | | | | solubility |

The result shown in Table 1 indicates that addition of diol compounds according to the invention inhibits blanket piling and decreases the reduction ratio of dot values. Furthermore, addition of diol compounds does not aggravate ink-stain (ink feedback) on the dampening roller. Among diol compounds used for the present invention, 1,2-octanediol is particularly preferred.

In Examples 1 and 2, a concentrated solution having 50-200 fold higher concentration over the working solution was prepared, and the working solution was prepared by diluting the concentrated solution with tap water and used to confirm the same effect as described above could be observed.

### Examples 3-12

Exactly the same experiment as described in Example 2 was conducted except that propylene glycol mono-n-butyl ether and propylene glycol were replaced with the compounds shown in Table 2 below. In Example 12, isopropyl alcohol was used and the amount thereof to be added was increased to 15 fold higher (i.e. to 7.5%) than those of the compounds used in other examples (0.5%). In Example 12, even when water volume was increased, stains were still prone to occur by ink attachment to the non-image areas on the printed matter, unless the additive amount of isopropyl alcohol was increased. The results are shown in Table 2.

TABLE 2

| | | | | | Ink-stain |
|---|---|---|---|---|---|
| Ex | | | Blan- | Reduction | on |
| am- | | | ket | ratio of dot | dampening |
| ple | Compound 1 | Compound 2 | piling | value (%) | roller |
| 2 | Propylene | Propylene | 49 | 6 | ◯ |
| | glycol | glycol | | | |
| | mono-n-butyl | | | | |
| | ether | | | | |
| 3 | Ethylene glycol | Propylene | 52 | 8 | ◯ |
| | mono-n-butyl | glycol | | | |
| | ether | | | | |
| 4 | Ethylene glycol | Propylene | 52 | 8 | ◯ |
| | mono-t-butyl | glycol | | | |
| | ether | | | | |
| 5 | Ethylene glycol | Propylene | 58 | 8 | ◯ |
| | mono isopropyl | glycol | | | |
| | ether | | | | |
| 6 | Ethylene glycol | Propylene | 74 | 16 | Δ |
| | mono-n-hexane | glycol | | | |
| | ether | | | | |
| 7 | 3-ethoxy | Propylene | 70 | 18 | Δ |
| | 3-ethyl-1- | glycol | | | |
| | butanol | | | | |
| 8 | Propylene | Dipropylene | 56 | 6 | ◯ |
| | glycol mono-n- | glycol | | | |
| | butyl ether | | | | |
| 9 | Propylene | Tripropylene | 54 | 8 | ◯ |
| | glycol mono-n- | glycol | | | |
| | butyl ether | | | | |
| 10 | Propylene | Diethylene | 72 | 14 | Δ |
| | glycol mono-n- | glycol | | | |
| | butyl ether | | | | |
| 11 | Propylene | No additive | 70 | 16 | Δ |
| | glycol mono-n- | | | | |
| | butyl ether | | | | |
| 12 | Isopropyl | No additive | 68 | 16 | Δ |
| | alcohol | | | | |
| | (7.5 g/100 g) | | | | |

In Table 2, the compound of formula (I) was used in Examples 2, 3-5, and 8-11 whereas the compound of formula (II) was used in Examples 2 and 3-9. These results indicate that the effect of addition of diol compounds becomes prominent when the compounds of formula (I) and formula (II) are used in combination.

A concentrated solution having a concentration 50-fold higher than the working solution was prepared, and it was found out that use of the compounds of formula (I) and formula (II) was preferable in terms of solubility stability.

### Experimental Example 1

The same printing experiment as described in Example 2 was conducted except that the amounts of the diol compounds to be added were altered. As a result, it was revealed that the additive amount thereof is preferably not less than 0.05%, more preferably not less than 0.1%, and particularly preferably not less than 0.2%. On the other hand, an additive amount exceeding 1% was prone to aggravate ink-stain (ink feedback) on the dampening roller.

Furthermore, the same effect was observed when the additive amount of 1,2-octanediol was decreased to 70% and 1,2-hexanediol was added by 30%.

The results are shown in Table 3 below.

TABLE 3

| | | | | Ink-stain |
|---|---|---|---|---|
| | | | Reduction | on |
| 1,2-octanediol | 1,2-hexanediol | Blanket | ratio of dot | dampening |
| content (%) | content (%) | piling | value (%) | roller |
| 0.03 | — | 90 | 25 | ◯ |
| 0.05 | — | 60 | 10 | ◯ |
| 0.10 | — | 55 | 8 | ◯ |
| 0.20 | — | 51 | 7 | ◯ |
| 0.30 | — | 49 | 6 | ◯ |
| (Example 2) | | | | |
| 0.50 | — | 48 | 6 | ◯ |
| 0.70 | — | 48 | 6 | ◯Δ* |
| 1.00 | — | 45 | 6 | Δ |
| 1.10 | — | 44 | 6 | X |
| 0.21 | 0.09 | 48 | 6 | ◯ |

*◯Δ = an intermediate level between ◯ and Δ

### Examples 13-15

The same printing experiment as described in Example 2 was conducted by further adding 0.08 g of a water-soluble polymer compound. The results are shown in Table 4.

TABLE 4

| | | | | Ink-stain |
|---|---|---|---|---|
| | | | Reduction | on |
| | Water-soluble polymer | Blanket | ratio of dot | dampening |
| Example | compound | piling | value (%) | roller |
| Example 2 | none | 49 | 6 | ◯ |
| 13 | Crboxymethylcellulose | 60 | 11 | ◯ |
| 14 | Polyvinylpyrrolidone | 56 | 10 | ◯ |
| 15 | Collagen | 75 | 20 | Δ |

These results indicate that the effect of diol compound is impaired to some extent in combination with a water-soluble polymer compounds.

### Examples 16-21

The same printing experiment as described in Example 7 was conducted except that a pyrrolidone derivative or acetylene derivative shown in Table 5 was added at a concentration of 0.01%. The obtained results are shown in Table 5.

TABLE 5

| | | | Reduction | Ink-stain on |
|---|---|---|---|---|
| | Pyrrolidone derivative/ | Blanket | ratio of dot | dampening |
| Example | acetylene derivative | piling | value (%) | roller |
| 7 | No additive | 70 | 18 | Δ |
| 16 | Butylpyrrolidone | 66 | 13 | ◯ |
| 17 | Octylpyrrolidone | 50 | 6 | ◯ |
| 18 | 3,5-Dimethyl-1- | 65 | 12 | Δ |
| | hexyne-3-ol | | | |
| 19 | 3,6-Dimethyl-4- | 55 | 9 | ◯ |
| | octyne-3,6-diol | | | |
| 20 | 2,4,7,9-Tetramethyl-5- | 56 | 9 | ◯ |
| | decyne-4,7-diol | | | |
| 21 | Adduct compound of 4 | 52 | 7 | ◯ |
| | ethylene oxides to | | | |
| | 2,4,7,9-tetramethyl-5- | | | |
| | decyne-4,7-diol | | | |

### Examples 22-24, and Comparative Examples 12-19

Each fountain solution composition was prepared according to the following formulation with a variation of diol compounds as shown in Table 6. Formulation of the fountain solution composition (working solution) of use

| Ingredients | Additive amount | |
|---|---|---|
| Compound of formula (IV) | 0.06 | g |
| (a = c = e = g = 1, b = d = f = h = 3, | | |
| molecular weight: 977) | | |
| Polyvinylpyrrolidone | 0.01 | g |
| Carboxymethylcellulose | 0.05 | g |
| Diol compounds shown in Table 6 | 0.30 | g |
| D-sorbitol | 0.40 | g |
| Ammonium nitrate | 0.02 | g |
| Dibasic ammonium citrate | 0.02 | g |
| 2,2-dibromo-2-nitroethanol | 0.002 | g |
| Benzotriazole | 0.002 | g |
| Water | up to 100 | g in total |

The same experiment was conducted as described in Example 1, but using these fountain solution compositions. The results are shown in Table 6. It should be noted that polyvinylpyrrolidone and carboxymethylcellulose were removed from the above formulation in Example 24.

TABLE 6

| | | | | Reduction ratio | Ink-stain on | |
|---|---|---|---|---|---|---|
| | | | Blanket | of dot value | dampening | |
| Example | | Diol compound | piling | (%) | roller | Remarks |
| Example | 22 | 1,2-hexanediol | 66 | 10 | ◯ | |
| | 23 | 1,2-octanediol | 50 | 8 | ◯ | |
| | 24 | 1,2-octanediol | 50 | 8 | Δ | * |
| Comparable | 12 | No additive | 100 | 33 | ◯ | |
| Example | | | | | | |
| | 13 | 1,2-butanediol | 98 | 29 | Δ | |
| | 14 | 1,2-pentanediol | 98 | 26 | ◯ | |
| | 15 | 1,2-decanediol | 94 | 28 | Δ | poor |
| | | | | | | solubility |
| | 16 | 1,3-octanediol | 96 | 31 | ◯ | |
| | 17 | 1,8-octanediol | 100 | 27 | Δ | |
| | 18 | 1,3-decanediol | 102 | 29 | X | poor |
| | | | | | | solubility |
| | 19 | 1,10- | 96 | 27 | X | poor |
| | | decanediol | | | | solubility |

* Polyvinylpyrrolidone and carboxymethylcellulose are not included.

### Experimental Example 2

The same printing experiment as described in Example 2 was performed except that the ink used for the experiment was changed as follows to confirm the effect of the fountain solution composition of the invention.

TOYO INK MFG CO., LTD.

| | |
|---|---|
| Super LeoEcoo SOY: | cyan, magenta, yellow |
| LeoEcoo SOY: | black, cyan, magenta, yellow |
| LeoEcoo LTD pro: | black, cyan, magenta, yellow |

TOKYO PRINTING INK MFG. CO., LTD.

| | |
|---|---|
| WEB ACTUS SOY Major: | black, cyan, magenta, yellow |

DIC Corporation

| | |
|---|---|
| New ADVAN: | black, cyan, magenta, yellow |

THE INCTEC INC.

| | |
|---|---|
| SOYBI VISTA: | black, cyan, magenta, yellow |

The same effects as described in Example 2 were observed for all inks for rotary offset of heat-set types listed above. The inks for which the fountain solution composition of the invention can be used are not limited to these, and the composition of the invention can be effectively used for fluorescent inks, mat inks, and a variety of neutral colour inks.

The fountain solution composition of the invention is also useful for rotary offset inks of non-heatset type used for printing of news papers and inks for sheet-fed process other than rotary offset inks of heat-set types. In particular, rotary offset inks of heat-set types are preferable since the effect of the fountain solution composition of the invention can be prominently excised in these inks.

What is claimed is:

1. A fountain solution composition for lithographic printing characterized by comprising at least one acyclic hydrocarbon diol compound, having 6 to 8 carbon atoms in total and two —OH groups, wherein said two —OH groups bind to carbon atoms at 1- and 2-positions, respectively.

2. The fountain solution composition for lithographic printing of claim 1, wherein said diol compound is 1,2-octanediol.

3. The fountain solution composition for lithographic printing of claim 1, further comprising at least one compound of formula (I) shown below, and at least one compound of formula (II) shown below.
R¹—O—(CH₂CHR²O)ₘ—H (I)
where R¹ represents an alkyl group having 1 to 4 carbon atoms, R² represents a hydrogen atom or methyl group, and m represents an integer of 1 to 3.
HO—(CH₂CH(CH₃)O)ₙ—H (II)
where n represents an integer of 1 to 5.

4. The fountain solution composition for lithographic printing according to claim 1, wherein said composition does not contain a water-soluble polymer compound.

5. The fountain solution composition for lithographic printing according to claim 1, further comprising at least one compound selected from an adduct compound of ethylene oxide and propylene oxide to ethylenediamine and an adduct compound of ethylene oxide and propylene oxide to diethylenetriamine.

6. The fountain solution composition for lithographic printing according to claim 1, further comprising a pyrrolidone derivative represented by the following general formula (VI): 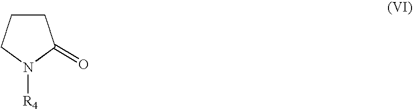
wherein R₄ represents an alkyl group having 2 to 12 carbon atoms.

7. The fountain solution composition for lithographic printing according to claim 1, further comprising at least one selected from the group consisting of acetylene glycols, acetylene alcohols, and an adduct compound of ethylene oxide and/or propylene oxide thereto.

8. A rotary heat-set offset printing process using ink for rotary offset of a heat-set type and the fountain solution composition according to claim 1.
